(19) United States
(12) Patent Application Publication
(10) Pub. No.: US 2005/0110120 A1
(43) Pub. Date: May 26, 2005

(54) Scribe line structure of wafer

(76) Inventors: Kun-Chih Wang, Hsinchu City (TW); Paul Chen, Hsinchu City (TW); Jui-Meng Jao, Miaoli County (TW); Chien-Li Kuo, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/707,222

(22) Filed: Nov. 27, 2003

(30) Foreign Application Priority Data
Nov. 20, 2003 (TW) 92132504

(51) Int. Cl. H01L 29/06

(52) U.S. Cl. 257/622

(57) ABSTRACT

A wafer scribe line structure is provided. A plurality of lump patterns is set up to fill the entire scribe line area so that the amount of stress the wafer is subjected to during a dicing process is reduced, thereby reducing the probability of having a delamination at the interface of wafer layers. Moreover, the lump patterns can be formed simultaneously with metal interconnects in a metal interconnect process.

### CROSS REFERENCE TO RELATED APPLICATIONS

This application claims the priority benefit of Taiwan application serial no. 92132504, filed on Nov. 20, 2003.

### BACKGROUND OF INVENTION

1. Field of the Invention

The present invention relates to a semiconductor wafer structure. More particularly, the present invention relates to a scribe line structure of wafer.

2. Description of the Related Art

Nowadays, integrated circuits (ICs) are used almost everywhere. However, the process of fabricating integrated circuits is complicated and involves four major stages: IC designs, wafer fabrication, wafer testing and wafer packaging. The total number of steps for fabricating an IC chip frequently exceeds a few hundreds and takes about a month or two for the completion of all necessary steps.

At present, semiconductor devices are formed on mono-crystalline silicon wafer. To lower production cost and to mass-produce chips, the diameter of a wafer has steadily increased from four inches to eight inches or more so that more chips can be fabricated on a single silicon wafer. The fabrication of integrated circuit devices can be roughly divided into three major stages, namely, silicon chip fabrication, integrated circuit fabrication and integrated circuit device packaging. In the integrated circuit fabrication stage, a number of patterns such as alignment marks, monitoring and/or measuring patterns, electrical testing patterns and product codes are formed on wafer scribe lines. Thereafter, the wafer is sawn to produce individual chip ready for carrying out the complicated integrated circuit packaging process.

However, various monitoring patterns on the scribe lines often subject the wafer chip on each side of the scribe lines to intense stress during the dicing process. As a result, chipping and delamination may appear close to the edges of the chip. Serious delamination is particularly likely to occur at the interface between a low dielectric constant material layer and another material layer because the low dielectric constant material layer often has a poor adhesion with other dielectric material layer or metal layer.

### SUMMARY OF INVENTION

Accordingly, at least one object of the present invention is to provide a wafer scribe line structure capable of reducing the amount of stress the wafer is subjected to during a dicing process.

At least a second object of this invention is to provide a wafer scribe line structure capable of preventing the growth of long chipping and the delamination of layers during a dicing process.

To achieve these and other advantages and in accordance with the purpose of the invention, as embodied and broadly described herein, the invention provides a wafer scribe line structure. The wafer has a low dielectric constant material layer thereon. Furthermore, a plurality of lump patterns is formed in the low dielectric constant material layer within the scribe line. Each lump pattern is constructed using at least a metal layer or a metal plug. Moreover, the lump patterns form a cyclical staggered array that fills up the scribe line entirely.

This invention also provides an alternative wafer scribe line structure. The scribe line on the wafer also incorporates a plurality of processing or testing patterns aside from a plurality of lump patterns embedded within a low dielectric constant material layer. Each lump pattern is constructed using at least a metal layer or a metal plug. Moreover, the lump patterns form a cyclical staggered array that fills up the scribe line entirely.

Since a plurality of lump patterns is formed within the low dielectric constant material layer of the scribe line in this invention, the amount of stress the wafer subjected to during the dicing process is greatly reduced. Hence, the probability of having a delamination at the interface between the low dielectric constant material layer and a nearby layer is also reduced.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a wafer scribe line structure according to one preferred embodiment of this invention.

FIG. 1B is a magnified cross-sectional view along line A-A″ in FIG. 1A.

FIGS. 2A, 2B, 3A and 3B are schematic cross-sectional views showing a few examples for the scribe line structure according to this invention.

FIG. 4 is a top view of a wafer scribe line structure according to another preferred embodiment of this invention.

FIG. 5 is a top view of a wafer scribe line structure according to yet another embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

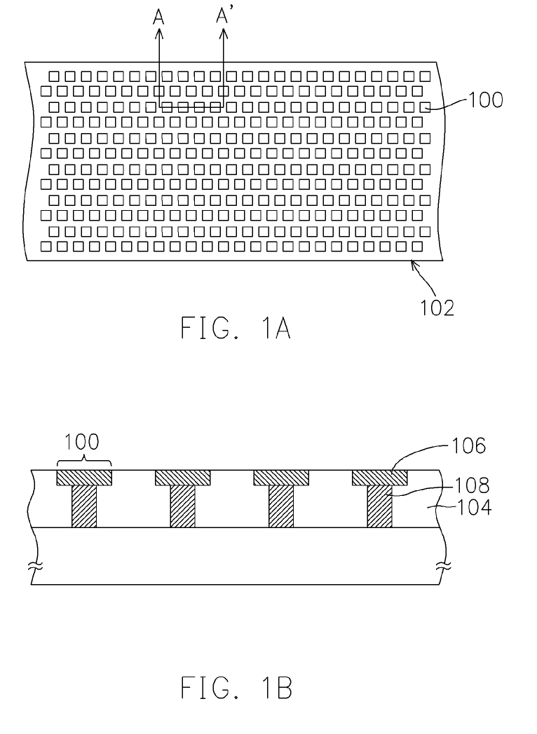

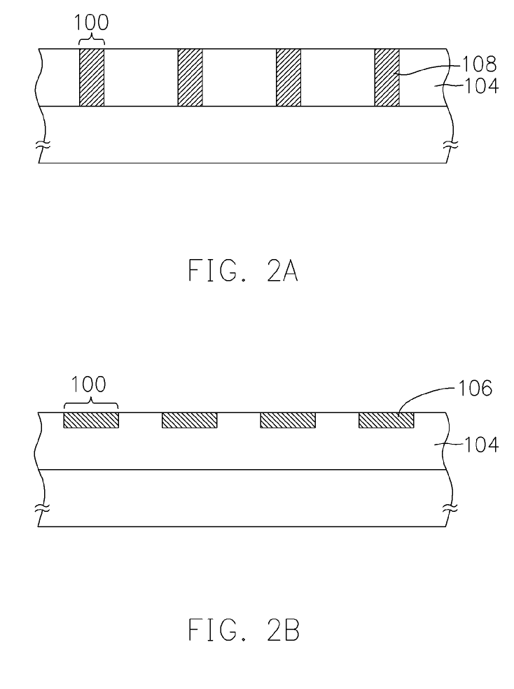

FIG. 1A is a top view of a wafer scribe line structure according to one preferred embodiment of this invention. FIG. 1B is a magnified cross-sectional view along line A-A″ in FIG. 1A. As shown in FIGS. 1A and 1B, the wafer scribe line structure comprises a plurality of lump patterns 100 in a low dielectric constant material layer 104 within a scribe line 102. Furthermore, the lump patterns 100 form a cyclically staggered array that fills the scribe line 102 entirely so that the amount of stress the wafer subjected to during a dicing process is reduced. The width of each scribe line 102 is about 110 μm, for example. The shape and size of all lump patterns 100 are identical, for example. The lump pattern 100 can have a variety of geometric shapes when viewing down from the top, and possible shapes for the lump patterns 100 include squares, rectangles, diamonds, triangles, circles, pentagons, hexagons or octagons. In this embodiment, an array of square lump patterns fills up the scribe line. In addition, the lump patterns 100 are formed in the low dielectric constant material layer 104 in the metal interconnect process simultaneously with the formation of metal layers or metal plugs, for example. In other words, each lump pattern 100 may be constructed from the attachment of a metal layer 106 to a metal plug 108. However, each lump pattern 100 may also be constructed from a metal plug 108 or a metal layer 106 alone as shown in FIGS. 2A and 2B.

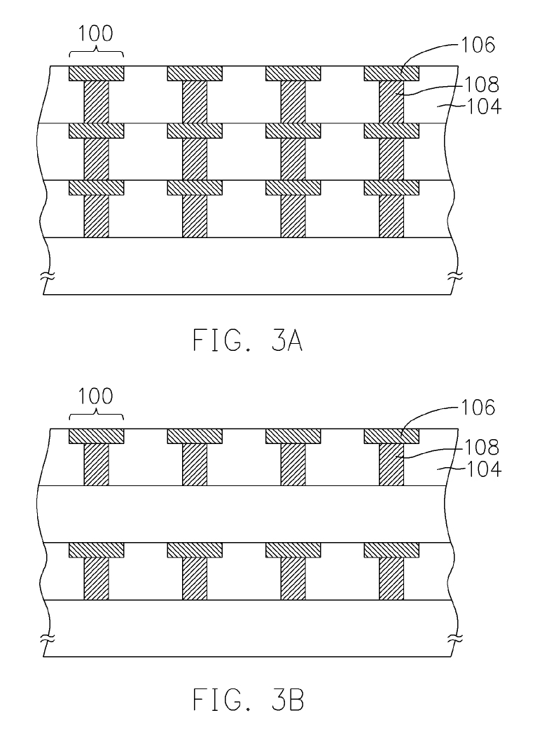

In this invention, there is no restriction on the way the metal layers 106 and the metal plugs 108 are joined together to form the lump patterns 100. Furthermore, the lump patterns 100 may be constructed using a multiple of metal layer 106/metal plug 108 sheets as shown in FIGS. 3A and 3B. Moreover, the metal layer 106/metal plug 108 sheets are in direct contact with each other (as shown in FIG. 3A) or are interrupted by an intermediate layer (as shown in FIG. 3B).

In another embodiment of this invention, the wafer scribe line structure has processing or testing patterns aside from the lump patterned within the low dielectric constant material layer. In the following, a more detailed description of the embodiment is provided. However, since devices with identical labels to the aforementioned embodiment are fabricated using the same material and fabricating method, detailed description of such is omitted.

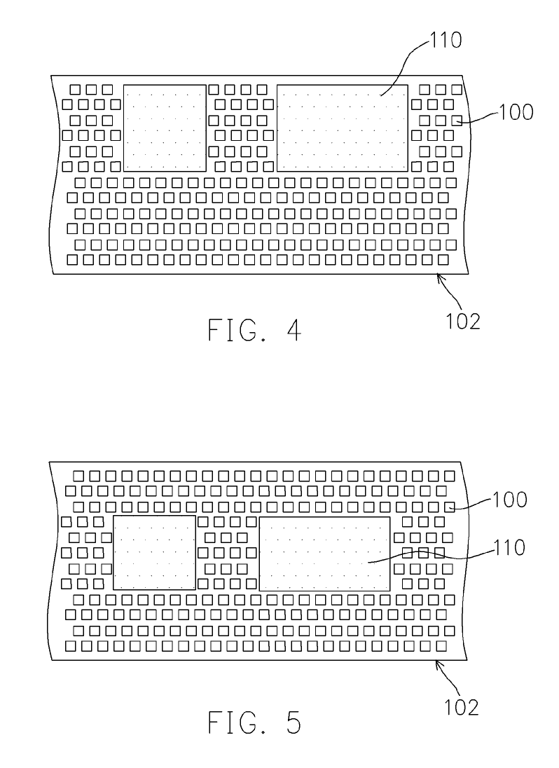

FIG. 4 is a top view of a wafer scribe line structure according to another preferred embodiment of this invention. As shown in FIG. 4, processing or testing patterns 110 and lump patterns 100 are formed within a scribe line 102. The patterns 110 are, for example, alignment marks, process-monitoring/measuring patterns, electrical testing patterns or product identification marks. Furthermore, these marks are set up adjacent to the boundary of the scribe line 102 and occupied an area of 80×70 μm², for example. In addition, the lump patterns 100 are set up within the low dielectric constant material layer in other parts of the scribe line 102. The lump patterns 100 are arranged to form a cyclically staggered array surrounding three sides of the patterns 110.

In another embodiment, the processing or testing patterns 110 may be set in the middle of the scribe line 102 so that the lump patterns 100 surround the patterns 110 on all four sides. FIG. 5 is a top view of a wafer scribe line structure according to yet another embodiment of this invention. As shown in FIG. 5, the lump patterns 100 are set up in regions outside the processing or testing patterns 110 within the scribe line 102. The lump patterns 100 are arranged to form a cyclically staggered array surrounding the patterns 110.

In summary, a plurality of cyclically staggered lump patterns is formed to cover the scribe line so that the amount of stress the wafer subjected to during a dicing process is greatly reduced. This prevents the growth of chipping near the cutting edges of a wafer chip and the delamination of the interface between the low dielectric constant material layer and a nearby layer. Furthermore, the lump patterns can be formed simultaneously with the metal interconnects in a metal interconnect fabrication process. Thus, the fabrication process is simplified and production yield is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A scribe line structure on a wafer having a low dielectric constant material layer thereon, wherein a plurality of lump patterns is set up in the low dielectric constant material layer within the scribe line such that the lump patterns pave the scribe line area almost completely, and the lump patterns are arranged to form a cyclically staggered array.

2. The scribe line structure of claim 1, wherein each lump pattern has an identical shape.

3. The scribe line structure of claim 2, wherein the shape of each lump pattern is selected from the group at least consisting of a square, a rectangle, a triangle, a rhombus, a circle, a pentagon, a hexagon and an octagon.

4-5. (canceled)

6. The scribe line structure of claim 1, wherein each lump pattern comprises at least one of a metal layer and a metal plug.

7. The scribe line structure of claim 6, wherein each lump pattern comprises at least one of a metal layer and a metal plug connected to each other.

8. The scribe line structure of claim 7, wherein the scribe line has multiple sheets of lump patterns such that the metal layer/metal plug pairs in each sheet are aligned and stacked over each other directly.

9. The scribe line structure of claim 7, wherein the scribe line has multiple: sheets of lump patterns such that each sheet with metal layer/metal plug pairs therein are separated from a nearby sheet by an intermediate layer.

10. A scribe line structure on a wafer having a low dielectric constant material layer thereon, wherein at least a wafer processing or testing pattern is set up within the scribe line and a plurality of lump patterns is set up in the low dielectric constant material layer within the scribe line such that the lump patterns pave the scribe line area outside the processing or testing pattern almost completely, and the lump patterns are arranged to form a cyclically staggered array.

11. The scribe line structure of claim 10, wherein the wafer processing or testing pattern is surrounded by the lump patterns.

12. The scribe line structure of claim 10, wherein the wafer processing or: testing pattern is adjacent to one of the boundaries of the scribe line so that no lump pattern is set up between the processing or testing pattern and its adjacent scribe line boundary.

13. The scribe line structure of claim 10, wherein each lump pattern has an identical shape.

14. The scribe line structure of claim 13, wherein the shape of each lump pattern is selected from the group at least consisting of a square, a rectangle, a triangle, a rhombus, a circle, a pentagon, a hexagon and an octagon.

15-16. (canceled)

17. The scribe line structure of claim 10, wherein each lump pattern comprises at least one of a metal layer and a metal plug.

18. The scribe line structure of claim 17, wherein each lump pattern comprises at least one of a metal layer and a metal plug connected to each other.

19. The scribe line structure of claim 18, wherein the scribe line has multiple sheets of lump patterns such that the metal layer/metal plug pairs in each sheet are aligned and stacked over each other directly.

20. The scribe line structure of claim 18, wherein the scribe line has multiple sheets of lump patters such that each sheet with metal layer/metal plug pairs therein is separated from a nearby sheet by an intermediate layer.

21. The scribe line structure of claim 10, wherein the wafer processing or testing patterns are selected from the group consisting of alignment marks, process-monitoring/measuring patterns, electrical testing patterns and product identification marks.
